(19) United States
(12) Patent Application Publication
(10) Pub. No.: US 2026/0118773 A1
(43) Pub. Date: Apr. 30, 2026

(54) SELF-EXCITATION LITHOGRAPHY METHOD WITH SELF-ALIGNMENT EFFECT

(71) Applicant: INSTITUTE OF MICROELECTRONICS, CHINESE ACADEMY OF SCIENCES, Beijing (CN)

(72) Inventors: Libin Zhang, Beijing (CN); Dinghai Rui, Beijing (CN); Yayi Wei, Beijing (CN); Yajuan Su, Beijing (CN)

(21) Appl. No.: 19/372,748

(22) Filed: Oct. 29, 2025

(30) Foreign Application Priority Data
Oct. 31, 2024 (CN) 202411540305.1

(51) Int. Cl. G03F 7/00

(52) U.S. Cl. CPC G03F 7/70466; G03F 7/0035; G03F 7/705; G03F 7/70575

(57) ABSTRACT

A self-excitation lithography method with a self-alignment effect. During the first lithography processing, the first mask is used merely to define an effective lithography region for the second lithography processing. Therefore, the first mask may be of a relatively large size, thereby greatly reducing the manufacturing difficulty of the first mask. Since the first metal layer and the second metal layer are both material layers having a negative refractive index, and a thickness difference exists in the second photoresist layer respectively corresponding to the first metal layer and the second metal layer, after performing simulation and optimization, resolution enhancement can be achieved in the region corresponding to the protruding structure, thereby realizing a self-alignment lithographic-pattern imaging with the self-excitation effect only in the region corresponding to the protruding structure.

### CROSS-REFERENCE TO RELATED APPLICATION

This application claims priority to Chinese Patent Application No. 202411540305.1, filed on Oct. 31, 2024, which is hereby incorporated by reference in its entirety.

### FIELD The present disclosure relates to the technical field of semiconductor processes, and in particular to a self-excitation lithography method with a self-alignment effect.

### BACKGROUND

A lithography technology is used for accurately imaging a target pattern onto a substrate. Existing mature lithography technologies include a deep ultraviolet lithography technology, an extreme ultraviolet lithography technology, an optical lithography technology, and the like.

Based on principles of optics, a lithography dimension limit of the above lithography technologies is constrained by an optical diffraction limit. For the lithography technology based on the deep ultraviolet, a resolution limit in a single lithography operation using an immersion lithography technology is 38 nm (a minimum pitch of 76 nm), while a resolution limit in commercial mass production is 40 nm (a pitch of 80 nm). When a wavelength of light is 193nm and water-immersion lithography is adopted, the resolution limit is about 20% of the wavelength.

For the existing lithography technologies, it is difficult to achieve resolution enhancement beyond the diffraction limit. For existing super-diffraction imaging techniques, existing methods employ proportionally scaled masks, resulting in extremely high mask fabrication difficulty. For imaging methods that achieve self-excitation through single apertures or similar features, it is difficult to achieve region-selective imaging.

### SUMMARY

In view of the foregoing issues, a self-excitation lithography method with a self-alignment effect is provided according to the present disclosure, where the mask has a relatively large size, thereby greatly reducing the manufacturing difficulty, and achieving region-selective imaging. The following solutions are provided.

In a first aspect of the present disclosure, a self-excitation lithography method with a self-alignment effect is provided, and the self-excitation lithography method includes: providing a to-be-processed structure, where the to-be-processed structure includes a substrate and a first photoresist layer arranged at a side of the substrate; performing first lithography processing and pattern transfer processing on the first photoresist layer based on a first mask to form a plurality of groove structures and at least one protruding structure on a surface of the substrate, where each protruding structure is provided between every two adjacent groove structures of the plurality of groove structures; forming a film layer and a first metal layer sequentially on the plurality of groove structures and the at least one protruding structure, where a height of the film layer on the plurality of groove structures is smaller than a height of the film layer on the protruding structure, and a height of the first metal layer on the plurality of groove structures is smaller than a height of the first metal layer on the protruding structure; forming a second photoresist layer on a side of the first metal layer away from the substrate, where a side of the second photoresist layer away from the substrate is parallel to a plane on which the substrate is located; forming a second metal layer on the side of the second photoresist layer away from the substrate, where a side of the second metal layer away from the substrate is parallel to the plane on which the substrate is located, and the first metal layer and the second metal layer are both material layers having a negative refractive index; determining a wavelength of collimated light having interference properties, performing simulation and optimization on thicknesses of film layers and a width of the protruding structure based on the wavelength of the collimated light, performing second lithography processing by using the collimated light to irradiate from the side of the second metal layer away from the substrate to perform a self-excitation selective-lithography on the second photoresist layer formed on the protruding structure, so as to form a target pattern; and transferring the target pattern onto the substrate.

In an embodiment, in the self-excitation lithography method with a self-alignment effect described above, the performing simulation and optimization on thicknesses of film layers and a width of the protruding structure based on the wavelength of the collimated light, performing second lithography processing by using the collimated light to irradiate from the side of the second metal layer away from the substrate to perform a self-excitation selective-lithography on the second photoresist layer formed on the protruding structure, so as to form a target pattern includes: performing simulation and optimization on thicknesses of the film layer, the first metal layer, the photoresist layer, and the second metal layer, and the width of the protruding structure based on the wavelength of the collimated light, and performing the second lithography processing from the side of the second metal layer away from the substrate to perform the self-excitation selective-lithography on the second photoresist layer formed on the protruding structure, so as to form the target pattern.

In an embodiment, in the self-excitation lithography method with a self-alignment effect described above, a method for performing simulation and optimization includes a time-domain finite-difference method, a finite element method, or a rigorous coupled-wave analysis method.

In an embodiment, in the self-excitation lithography method with a self-alignment effect described above, the wavelength of the collimated light includes 193 nm, 248 nm, 365 nm, 436 nm, 532 nm or 633 nm.

In an embodiment, in the self-excitation lithography method with a self-alignment effect described above, where after transferring the target pattern onto the substrate, a region of the substrate corresponding to the protruding structure has a nanometer-scale structure.

In an embodiment, in the self-excitation lithography method with a self-alignment effect described above, where the performing first lithography processing and pattern transfer processing on the first photoresist layer based on a first mask to form a plurality of groove structures and at least one protruding structure on a surface of the substrate includes: performing the first lithography processing on the first photoresist layer based on the first mask, to obtain a processed first photoresist layer; and performing etching processing on the substrate based on the processed first photoresist layer to form the plurality of groove structures and the at least one protruding structure on the substrate, where each protruding structure is provided between every two adjacent groove structures of the plurality of groove structures.

In an embodiment, in the self-excitation lithography method with a self-alignment effect described above, a material of the first metal layer is the same as a material of the second metal layer.

In an embodiment, in the self-excitation lithography method with a self-alignment effect described above, the transferring the target pattern onto the substrate includes: removing the second metal layer; performing etching processing on the first metal layer based on the second photoresist layer to obtain an etched first metal layer, and removing the second photoresist layer; performing etching processing on the film layer based on the etched first metal layer to obtain an etched film layer, and removing the etched first metal layer; and performing etch processing on the substrate based on the etched film layers, and removing the etched film layer.

In an embodiment, in the self-excitation lithography method with a self-alignment effect described above, the collimated light irradiates from the side of the second metal layer away from the substrate in a manner of normal incidence, or, in a manner of oblique incidence at a specific angle after being subject to light-source modulation, to perform the second lithography processing; and the incident light includes two or more collimated beams incident at oblique angles opposite from each other with respect to a normal.

In an embodiment, in the self-excitation lithography method with a self-alignment effect described above, a width of the protruding structure is of a micrometer scale, or of a 100-nanometer scale or more.

Based on the technical solution described above, the self-excitation lithography method with the self-alignment effect is provided in the present disclosure. During the first lithography processing, the first mask is used merely to define an effective lithography region for the second lithography processing. Therefore, the first mask may be of a relatively large size, thereby greatly reducing the manufacturing difficulty of the first mask. Since the first metal layer and the second metal layer are both material layers having a negative refractive index, and a thickness difference exists in the second photoresist layer respectively corresponding to the first metal layer and the second metal layer, after performing simulation and optimization on thicknesses of film layers and a width of the protruding structure based on the wavelength of the collimated light, resolution enhancement can be achieved in the region corresponding to the protruding structure, thereby realizing a self-alignment lithographic-pattern imaging with the self-excitation effect only in the region corresponding to the protruding structure. Moreover, no mask is used in the second lithography processing, which further reduces the process complexity.

### BRIEF DESCRIPTION OF THE DRAWINGS

The above and other features, advantages and aspects of the embodiments of the present disclosure will be more apparent in conjunction with the drawings and with reference to the following embodiments. The same or similar reference numerals throughout the drawings represent the same or similar elements. It should be understood that the drawings are schematic and the components and elements are unnecessarily drawn to scale.

FIG. 1 is a schematic flowchart of a self-excitation lithography method with a self-alignment effect according to an embodiment of the present disclosure;

FIG. 2 to FIG. 9 are schematic diagrams of structures corresponding to the self-excitation lithography method shown in FIG. 1;

FIG. 10 is a schematic diagram illustrating self-excitation resolution-enhanced imaging effects corresponding to different widths of a protruding structure according to an embodiment of the present disclosure;

FIG. 11 to FIG. 14 are schematic diagrams of partial structures corresponding to the self-excitation lithography method shown in FIG. 1; and

FIG. 15 is a schematic diagram illustrating a structure and an imaging effect corresponding to the technical solution according to an embodiment of the present disclosure.

### DETAILED DESCRIPTION

The embodiments of the present disclosure will be described as follows in conjunction with the drawings in the embodiments of the present disclosure. The terms in the embodiments of the present disclosure are only for the purpose of explaining specific embodiments of the present disclosure, rather than limiting the present disclosure. Those skilled in the art should understand that the technical solutions provided according to the embodiments of the present disclosure are still applicable to similar technical problems, despite the development of technologies and the emergence of different application scenarios.

The present disclosure is illustrated in detail in conjunction with the drawings and specific embodiments hereinafter, so that the above purposes, features and advantages of the present disclosure are apparent and understandable.

It should be noted that the orientation terms used in the present disclosure represent relative positional relationships shown in the drawings and do not constitute an absolute limitation on the present disclosure.

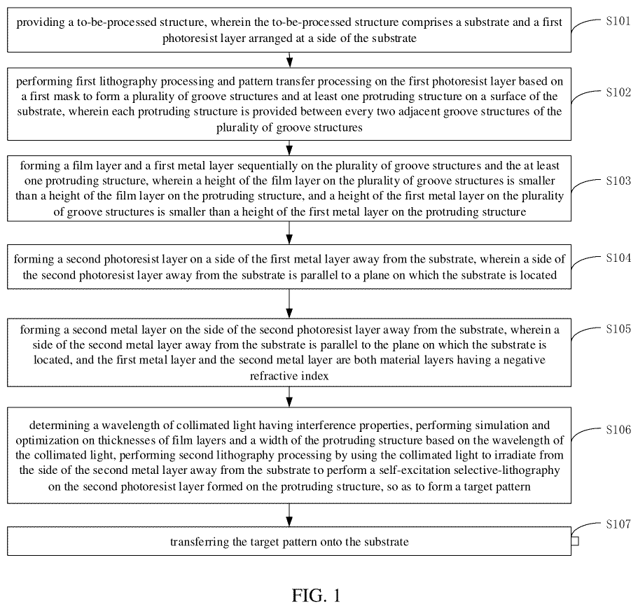

Reference is made to FIG. 1, which is a schematic flowchart of a self-excitation lithography method with a self-alignment effect according to an embodiment of the present disclosure. The self-excitation lithography method with the self-alignment effect according to the embodiment of the present disclosure includes steps S101 to S107.

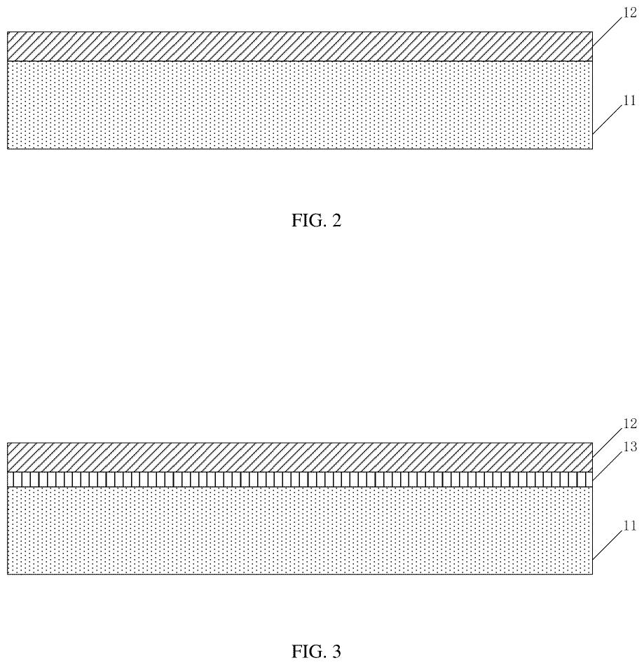

In step S101, as shown in FIG. 2, a to-be-processed structure is provided, where the to-be-processed structure includes a substrate 11 and a first photoresist layer 12 arranged at a side of the substrate 11.

In an embodiment, the substrate 11 includes, but is not limited to, a silicon substrate, a quartz substrate, or other group III-V substrates.

In an optional embodiment of the present disclosure, as shown in FIG. 3, the to-be-processed structure may further include an anti-reflective film layer 13 arranged between the substrate 11 and the first photoresist layer 12. By providing the anti-reflective film layer 13, the quality of the lithography performed on the first photoresist layer 12 in subsequent processes can be improved.

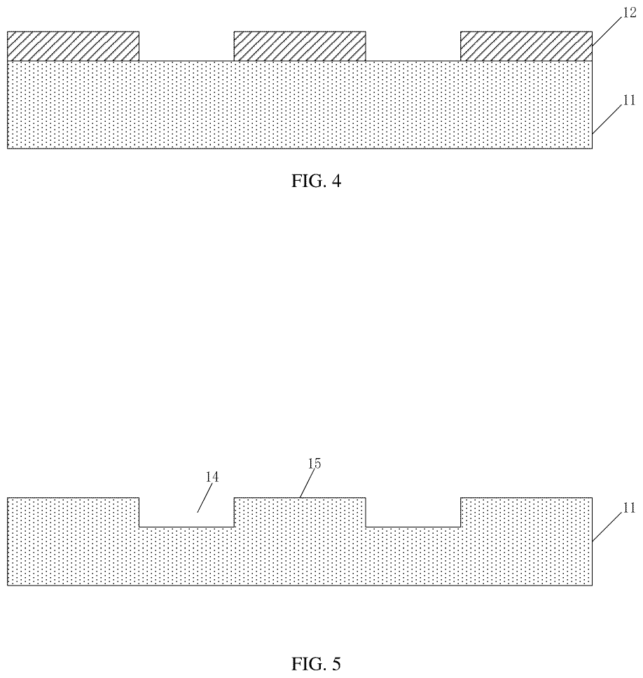

In step S102, as shown in FIGS. 4 and 5, first lithography processing and pattern transfer processing are performed on the first photoresist layer 12 based on a first mask to form multiple groove structures 14 and at least one protruding structure 15 on the substrate 11, where each protruding structure 15 is provided between every two adjacent groove structures of the multiple groove structures 14.

One possible implementation for performing the first lithography processing and the pattern transfer processing on the first photoresist layer 12 based on the first mask to form multiple groove structures 14 and at least one protruding structure 15 on the substrate 11 may include:
as shown in FIG. 4, performing the first lithography processing on the first photoresist layer 12 based on the first mask, to obtain a processed first photoresist layer; and
as shown in FIG. 5, performing etching processing on the substrate 11 based on the processed first photoresist layer 12, to form multiple groove structures 14 and the at least one protruding structure 15 on the substrate 11, where each protruding structure 15 is provided between every two adjacent groove structures 14.

In the first lithography processing, the first mask is only used for defining an effective lithography region for second lithography processing. Therefore, the first mask may be a mask of a relatively-large size. A minimum size of the first mask is greater than a micrometer or hundreds of nanometers, and the first mask can be obtained by a conventional lithography method. Size-related settings of the first mask may include settings such as an equal-width setting or an equal-spacing setting, which are determined based on a target lithography process and material characteristics, and is not specifically limited in the embodiments of the present disclosure.

As shown in FIG. 4, the first lithography processing may be performed by an optical lithography or other lithography techniques. After applying the first mask, imaging on the first photoresist layer 12 is achieved.

As shown in FIG. 5, the pattern formed after the first lithography processing is transferred onto the substrate 11 by a process including, but not limited to, etching. In an embodiment of the present disclosure, after the pattern is transferred, the pattern is formed as a structure with a width of a micrometer scale on the substrate 11. It can be understood that the width of the protruding structure 15 is of the micrometer scale. That is, the width of the protruding structure 15 is of the micrometer scale, or of the 100-nanometer scale or more.

That is, in the embodiments of the present disclosure, the first lithography processing is performed using the first mask with a relatively-large dimension to define a specific region. In the embodiments of the present disclosure, the specific region is exemplified by a region to which the protruding structure 15 corresponds.

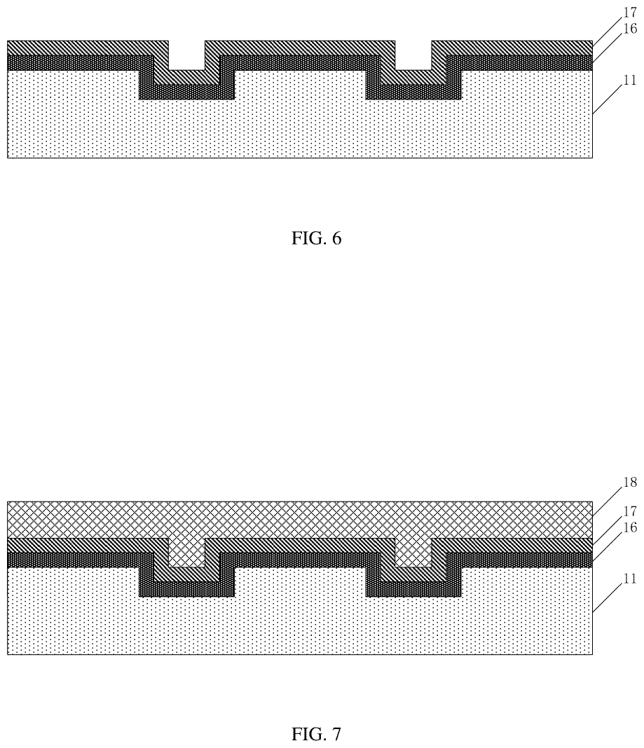

In step S103, as shown in FIG. 6, a film layer 16 and a first metal layer 17 are sequentially formed on the multiple groove structures 14 and the at least one protruding structure 15, where a height of the film layer 16 on the multiple groove structures 14 is smaller than a height of the film layer 16 on the protruding structure 15, and a height of the first metal layer 17 on the multiple groove structures 14 is smaller than a height of the first metal layer 17 on the protruding structure 15.

In an embodiment, the film layer 16 and the first metal layer 17 may be formed by, but not limited to, a deposition process. When the film layer 16 and the first metal layer 17 are formed by the deposition process, conformal film growth with the surface of the substrate 11 can be achieved. That is, a portion of the film layer 16 and a portion of the first metal layer 17 in the region of the protruding structure 15 are both higher than those in the region of the groove structure 14.

In the embodiments of the present disclosure, the material of the film layer 16 includes, but is not limited to, a silicon oxide material, and the material of the first metal layer 17 includes, but is not limited to, a silver material.

In step S104, as shown in FIG. 7, a second photoresist layer 18 is formed on a side of the first metal layer 17 away from the substrate 11, where a side of the second photoresist layer 18 away from the substrate 11 is parallel to a plane on which the substrate 11 is located.

In an embodiment, the second photoresist layer 18 may be formed by, but not limited to, a spin-coating process. In the spin-coating process, a spin coater is used to perform spin coating on the surface of the structure shown in FIG. 6 with the photoresist, thereby achieving a planar surface of the second photoresist layer 18. It can be understood that the side of the formed second photoresist layer 18 away from the substrate 11 is parallel to the plane on which the substrate 11 is located.

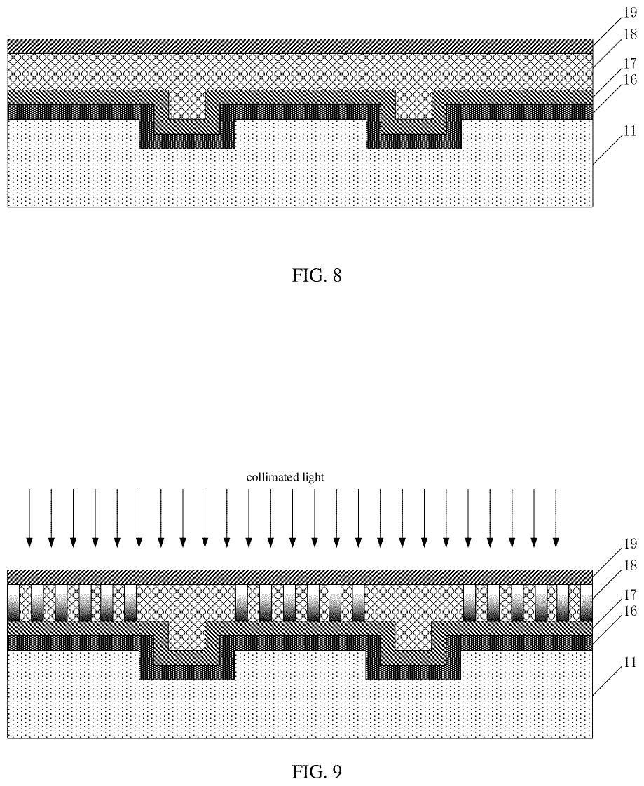

In step S105, as shown in FIG. 8, a second metal layer 19 is formed on the side of the second photoresist layer 18 away from the substrate 11, where a side of the second metal layer 19 away from the substrate 11 is parallel to the plane on which the substrate 11 is located, and the first metal layer 17 and the second metal layer 19 are both material layers having a negative refractive index.

In an embodiment, the second metal layer 19 may be formed by, but not limited to, a deposition process. Since the second photoresist layer 18 has a planar surface, the second metal layer 19 may also have a planar surface after being formed. It can be understood that the side of the formed second metal layer 19 away from the substrate 11 is parallel to the plane on which the substrate 11 is located.

As shown in FIG. 8, in this case, a thickness of a portion of the second photoresist layer 18 in the region of the groove structure 14 is greater than that of a portion of the second photoresist in the region of the protruding structure 15. It can be understood that a distance between the portion of the first metal layer 17 and the portion of the second metal layer 19 in the region of the groove structure 14 is greater than that the portion of the first metal layer 17 and the portion of the second metal layer 19 in the region of the protruding structure 15.

The first metal layer 17 and the second metal layer 19 are both material layers having a negative refractive index, thereby ensuring that the self-excitation lithography technique based on a material having a negative refractive index can be realized in the present technical solution. The material of the second metal layer 19 includes, but is not limited to, silver.

In an embodiment of the present disclosure, the material of the first metal layer 17 is the same as that of the second metal layer 19. For example, the materials of both the first metal layer 17 and the second metal layer 19 are silver.

In step S106, as shown in FIG. 9, a wavelength of collimated light having interference properties is determined, performing simulation and optimization on thicknesses of film layers and a width of the protruding structure 15 based on the wavelength of the collimated light, and performing second lithography processing by using the collimated light to irradiate from the side of the second metal layer 19 away from the substrate 11, to perform a self-excitation selective-lithography on the second photoresist layer 18 formed on the surface of the protruding structure 15, so as to form a target pattern.

In an embodiment, one possible implementation for performing simulation and optimization on thicknesses of film layers and a width of the protruding structure 15 based on the wavelength of the collimated light, and performing second lithography processing by using the collimated light to irradiate from the side of the second metal layer 19 away from the substrate 11, to perform a self-excitation selective-lithography on the second photoresist layer 18 formed on the surface of the protruding structure 15, so as to form a target pattern may include:
performing simulation and optimization on the thicknesses of the film layer 16, the first metal layer 17, the photoresist layer 18, and the second metal layer 19, and the width of the protruding structure 15 based on the wavelength of the collimated light, and performing the second lithography processing by using the collimated light to irradiate from the side of the second metal layer 19 away from the substrate 11, to perform the self-excitation selective-lithography on the second photoresist layer 18 formed on the surface of the protruding structure 15, so as to form the target pattern.

The method for performing simulation and optimization may be a time-domain finite-difference method, a finite element method, or a rigorous coupled-wave analysis method.

The wavelength of the collimated light may be 193 nm, 248 nm, 365 nm, 436 nm, 532 nm, 633 nm, or any wavelength ranging from a wavelength of the visible light to a wavelength of the ultraviolet light.

The collimated light having interference properties may be the collimated light with interference properties after being subject to light source modulation. The collimated light is used to irradiate the entire surface or a specific region of the to-be-processed structure (in the embodiment of the present disclosure, the region where the protruding structure 15 is located is taken as an example), so as to perform the second lithography processing.

As shown in FIG. 9, after the second lithography processing, a light-intensity-based equally-spaced feature (that is, the aforementioned target pattern) is formed in the specific region of the second photoresist layer 18, thereby achieving a self-excitation effect with enhanced resolution.

After performing simulation and optimization on the thicknesses of the film layer 16, the first metal layer 17, the photoresist layer 18, and the second metal layer 19, and the width of the protruding structure 15 based on the wavelength of the collimated light, specific regions can be determined, thereby achieving a region-selective lithography technique. Furthermore, a self-excitation effect will be generated through the obtained structure and the wavelength of the collimated light, thereby forming a nanometer-scale structure that can excite resolution enhancement through interference.

In summary, since the first metal layer 17 and the second metal layer 19 are both material layers having a negative refractive index, and a thickness difference exists in the second photoresist layer 18 respectively corresponding to the first metal layer 17 and the second metal layer 19, after performing simulation and optimization on thicknesses of film layers and a width of the protruding structure 15 based on the wavelength of the collimated light, resolution enhancement can be achieved in the region corresponding to the protruding structure 15, thereby realizing a self-alignment lithographic-pattern imaging with the self-excitation effect only in the region corresponding to the protruding structure 15. Moreover, no mask is used in the second lithography processing, which further reduces the process complexity.

In an embodiment of the present disclosure, the collimated light irradiates from the side of the second metal layer 19 away from the substrate 11 in a manner of normal incidence, or, in a manner of oblique incidence at a specific angle after being subject to light-source modulation, to perform the second lithography processing.

The incident collimated light includes two or more collimated beams incident at oblique angles opposite from each other with respect to a normal.

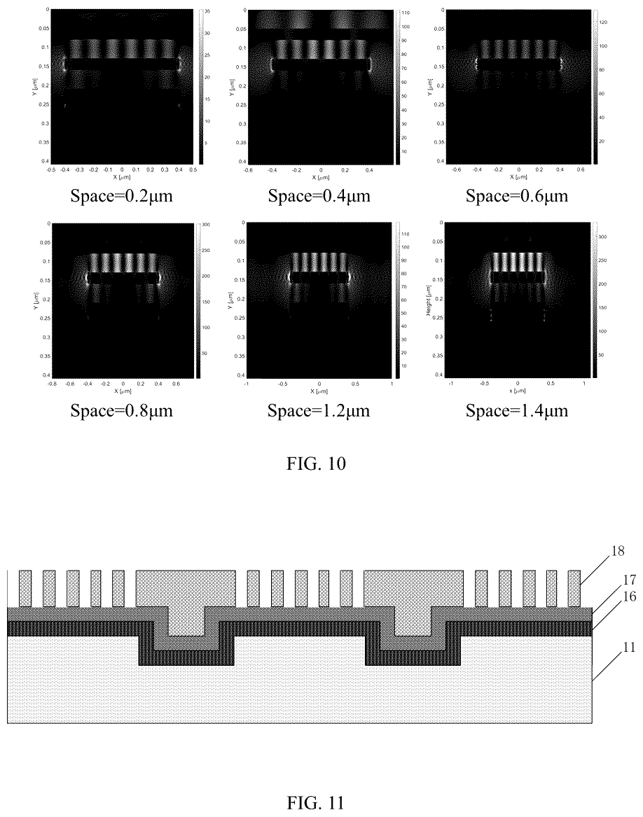

Due to extremely strict constraints imposed on the pattern dimension for self-excitation, an applicable range for self-excitation is generally very small. The structure in the technical solution of the present disclosure can greatly expand the region where the protruding structure is located. Referring to FIG. 10, which illustrates schematic diagrams of self-excitation resolution-enhanced imaging effects corresponding to different widths of the protruding structure provided in an embodiment of the present disclosure. In FIG. 10, the widths of the protruding structure 15 are exemplarily 0.2 μm, 0.4 μm, 0.6 μm, 0.8 μm, 1.2 μm, and 1.4 μm. That is, Space=0.2 μm, Space=0.4 μm, Space=0.6 μm, Space=0.8 μm, Space=1.2 μm, and Space=1.4 μm. Based on the results shown in FIG. 10, it can be seen that when using the protruding structures 15 of different widths, a satisfactory self-excitation resolution-enhanced imaging effect can be achieved.

In step S107, as shown in FIGS. 11 to 14, the target pattern is transferred onto the substrate 11.

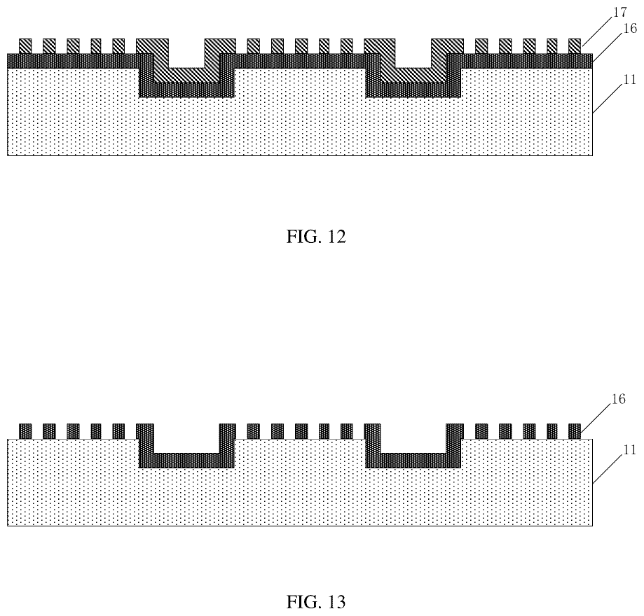

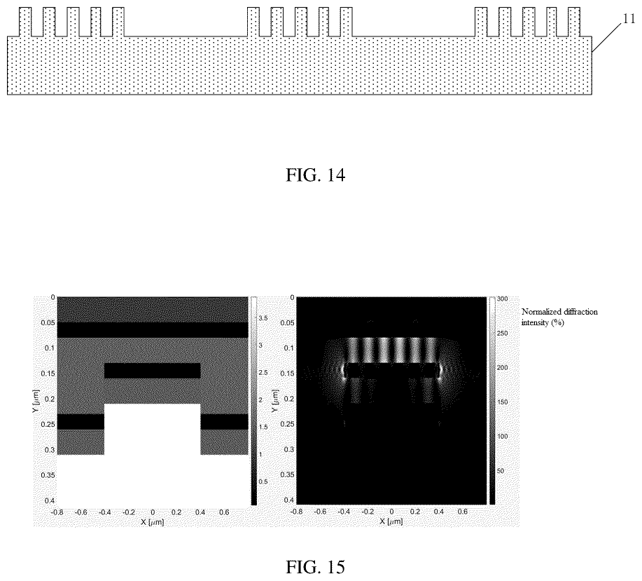

In an embodiment, one possible implementation of transferring the target pattern to the substrate 11 may include:
as shown in FIG. 11, removing the second metal layer 19, exposing and developing the second photoresist layer 18;
as shown in FIG. 12, performing etching processing on the first metal layer 17 based on the second photoresist layer 18 to obtain an etched first metal layer 17, and removing the second photoresist layer 18;
as shown in FIG. 13, performing etching processing on the film layer 16 based on the etched first metal layer 17 to obtain the etched film layer 16, and removing the etched first metal layer 17; and
as shown in FIG. 14, performing the etching processing on the substrate 11 based on the etched film layer 16, and removing the etched film layer 16.

In summary, transferring the target pattern on the substrate 11 includes the removal of the second metal layer 19 on the top, processes including developing and post-baking of the second photoresist layer 18, and etching of multiple material layers. The effect as shown in FIG. 14 is achieved. Here, only the specific region defined during the first lithography processing has the nanometer-scale structure. That is, after transferring the target pattern onto the substrate 11, only the region of the substrate 11 corresponding to the protruding structure 15 has the nanometer-scale structure.

Reference is made to FIG. 15, which is a schematic diagram illustrating the structure and imaging effect corresponding to the technical solution according to an embodiment of the present disclosure. Based on the results shown in FIG. 15, it can be seen that, in a case that the simulation and optimization are performed on the specific film layer structures and multiple parameters, i.e. a case in which simulation and optimization are performed on the thicknesses of film layers and the width of the protruding structure 15 based on the wavelength of the collimated light, resolution enhancement can be achieved in the region corresponding to the protruding structure 15. A sandwich structure including the second metal layer 19, the second photoresist layer 18, and the first metal layer 17 with different thicknesses is formed, in which the parameters such as the thicknesses of the film layers in different regions are optimized, thereby realizing a self-alignment lithographic-pattern imaging effect with self-excitation effect only generated in the region corresponding to the protruding structure 15.

The technical solution of the present disclosure achieves self-alignment lithography of the pattern obtained after the first lithography processing is performed, without considering overlay alignment errors caused by two times of lithography processing. Compared with conventional self-excitation, the second lithography processing achieves self-excitation only in specific regions determined after the first lithography processing, thereby achieving a region-selective effect. Moreover, lithography of a pattern with varying pitches can be achieved, thereby increasing the complexity of design rules for the lithography process.

The self-excitation lithography method with the self-alignment effect according to the present disclosure is introduced in detail above. The principles and implementations of the present disclosure are described with specific examples. The above descriptions of the embodiments are only used to facilitate understanding of the method and the core idea of the present disclosure. In addition, for those skilled in the art, variations may be made to the embodiments and the application range based on the idea of the present disclosure. Therefore, the specification should not be understood as limitation of the present disclosure.

It should be noted that all the embodiments in this specification are described in a progressive way, and each embodiment focuses on the differences from other embodiments. The same and similar parts among the embodiments can be referred to each other. Since the apparatus disclosed in the embodiments correspond to the method disclosed in the embodiments, the description of the apparatus is simple, and reference may be made to the relevant part of the method.

It should be further illustrated that relation terms such as “first” and “second” herein are only used to distinguish one entity or operation from another entity or operation, which does not necessarily require or imply that there is an actual relation or sequence between these entities or operations. Furthermore, terms of “include”, “comprise” or any other variants are intended to be non-exclusive. Therefore, a process, method, article or device including a series of elements includes not only the listed elements but also elements inherent in the process, method, article or device. In addition, unless expressively limited otherwise, the statement “comprising (including) a(n) . . . ” does not exclude existence of other identical elements in the process, method, article or device.

According to the above description of the disclosed embodiments, those skilled in the art can implement or practice the present disclosure. Various modifications to these embodiments are obvious to those skilled in the art, and the general principles defined herein may be implemented in other embodiments without departing from the spirit and scope of the present disclosure. Therefore, the present disclosure is not to be limited to the embodiments illustrated herein, but should be conformed to the widest scope consistent with the principles and novel features disclosed herein.

1. A self-excitation lithography method with a self-alignment effect, comprising:
providing a to-be-processed structure, wherein the to-be-processed structure comprises a substrate and a first photoresist layer arranged at a side of the substrate;
performing first lithography processing and pattern transfer processing on the first photoresist layer based on a first mask to form a plurality of groove structures and at least one protruding structure on a surface of the substrate, wherein each protruding structure is provided between every two adjacent groove structures of the plurality of groove structures;
forming a film layer and a first metal layer sequentially on the plurality of groove structures and the at least one protruding structure, wherein a height of the film layer on the plurality of groove structures is smaller than a height of the film layer on the protruding structure, and a height of the first metal layer on the plurality of groove structures is smaller than a height of the first metal layer on the protruding structure;
forming a second photoresist layer on a side of the first metal layer away from the substrate, wherein a side of the second photoresist layer away from the substrate is parallel to a plane on which the substrate is located;
forming a second metal layer on the side of the second photoresist layer away from the substrate, wherein a side of the second metal layer away from the substrate is parallel to the plane on which the substrate is located, and the first metal layer and the second metal layer are both material layers having a negative refractive index;
determining a wavelength of collimated light having interference properties, performing simulation and optimization on thicknesses of film layers and a width of the protruding structure based on the wavelength of the collimated light, performing second lithography processing by using the collimated light to irradiate from the side of the second metal layer away from the substrate to perform a self-excitation selective-lithography on the second photoresist layer formed on the protruding structure, so as to form a target pattern; and
transferring the target pattern onto the substrate.

2. The self-excitation lithography method with a self-alignment effect according to claim 1, wherein the performing simulation and optimization on thicknesses of film layers and a width of the protruding structure based on the wavelength of the collimated light, performing second lithography processing by using the collimated light to irradiate from the side of the second metal layer away from the substrate to perform a self-excitation selective-lithography on the second photoresist layer formed on the protruding structure, so as to form a target pattern comprises:
performing simulation and optimization on thicknesses of the film layer, the first metal layer, the photoresist layer, and the second metal layer, and the width of the protruding structure based on the wavelength of the collimated light, and performing the second lithography processing from the side of the second metal layer away from the substrate to perform the self-excitation selective-lithography on the second photoresist layer formed on the protruding structure, so as to form the target pattern.

3. The self-excitation lithography method with a self-alignment effect according to claim 2, wherein a method for performing simulation and optimization comprises a time-domain finite-difference method, a finite element method, or a rigorous coupled-wave analysis method.

4. The self-excitation lithography method with a self-alignment effect according to claim 1, wherein the wavelength of the collimated light comprises 193 nm, 248 nm, 365 nm, 436 nm, 532 nm or 633 nm.

5. The self-excitation lithography method with a self-alignment effect according to claim 1, wherein after transferring the target pattern onto the substrate, a region of the substrate corresponding to the protruding structure has a nanometer-scale structure.

6. The self-excitation lithography method with a self-alignment effect according to claim 1, wherein the performing first lithography processing and pattern transfer processing on the first photoresist layer based on a first mask to form a plurality of groove structures and at least one protruding structure on a surface of the substrate comprises:
performing the first lithography processing on the first photoresist layer based on the first mask, to obtain a processed first photoresist layer; and
performing etching processing on the substrate based on the processed first photoresist layer to form the plurality of groove structures and the at least one protruding structure on the substrate, wherein each protruding structure is provided between every two adjacent groove structures of the plurality of groove structures.

7. The self-excitation lithography method with a self-alignment effect according to claim 1, wherein a material of the first metal layer is the same as a material of the second metal layer.

8. The self-excitation lithography method with a self-alignment effect according to claim 1, wherein the transferring the target pattern onto the substrate comprises:
removing the second metal layer;
performing etching processing on the first metal layer based on the second photoresist layer to obtain an etched first metal layer, and removing the second photoresist layer;
performing etching processing on the film layer based on the etched first metal layer to obtain an etched film layer, and removing the etched first metal layer; and
performing etch processing on the substrate based on the etched film layers, and removing the etched film layer.

9. The self-excitation lithography method with a self-alignment effect according to claim 1, wherein the collimated light irradiates from the side of the second metal layer away from the substrate in a manner of normal incidence, or, in a manner of oblique incidence at a specific angle after being subject to light-source modulation, to perform the second lithography processing; and
the incident light comprises two or more collimated beams incident at oblique angles opposite from each other with respect to a normal.

10. The self-excitation lithography method with a self-alignment effect according to claim 1, wherein a width of the protruding structure is of a micrometer scale, or of a 100-nanometer scale or more.

11. The self-excitation lithography method with a self-alignment effect according to claim 2, wherein the wavelength of the collimated light comprises 193 nm, 248 nm, 365 nm, 436 nm, 532 nm or 633 nm.

12. The self-excitation lithography method with a self-alignment effect according to claim 3, wherein the wavelength of the collimated light comprises 193 nm, 248 nm, 365 nm, 436 nm, 532 nm or 633 nm.
